(19) United States
(12) Patent Application Publication
(10) Pub. No.: US 2010/0224866 A1
(43) Pub. Date: Sep. 9, 2010

(54) TERNARY EMISSIVE LAYERS FOR LUMINESCENT APPLICATIONS

(75) Inventor: Ying Wang, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I.Du pont de Nemours and Company, Wilmington, DE (US)

(21) Appl. No.: 12/682,848

(22) PCT Filed: Oct. 23, 2008
(86) PCT No.: PCT/US08/80888

§ 371 Date: Apr. 13, 2010

Related U.S. Application Data
(60) Provisional application No. 60/981,835, filed on Oct. 23, 2007.

(51) Int. Cl. H01L 51/54; H01L 51/52

(52) U.S. Cl. 257/40; 257/E51.018; 257/E51.026

(57) ABSTRACT

There is provided an organic light emitting diode having an anode, a hole transport layer containing a material having an ionization potential IP_{HTL}, an emissive layer, an electron transport layer, and a cathode. The emissive layer contains: (a) a fluorinated hexacoordinate iridium complex emitter having an ionization potential IPₑₘₜ; (b) an electron transport host material having an ionization potential IP_{HO}; and (c) a recombination zone shifting additive having an ionization potential IPₓ. The weight ratio of host to zone shifting additive is at least 4 and the following energy relationships exist: (i) (IP_{HTL}−IPₑₘₜ)≧−0.1 eV; (ii) IP_{HO}>IP_{HTL}; and (iii) IPₓ≦IP_{HTL}.

### RELATED APPLICATION

This application claims priority under 35 U.S.C. §119(e) from U.S. Provisional Application No. 60/981,835 filed on Oct. 23, 2007 which is incorporated by reference in its entirety.

### BACKGROUND INFORMATION

1. Field of the Disclosure

This disclosure relates in general to ternary combinations of materials that can be used as emissive layers for light-emitting materials in luminescent applications. The disclosure further relates to electronic devices having at least one active layer comprising such a ternary combination.

2. Description of the Related Art

In organic photoactive electronic devices, such as organic light emitting diodes (“OLEDs”), that make up OLED displays, one or more organic active layers are sandwiched between two electrical contact layers. At least one organic active layer is an emissive layer. In an OLED, the emissive layer emits light through the light-transmitting electrical contact layer upon application of a voltage across the electrical contact layers.

Typical OLED devices consist of an anode, a hole transport layer (“HTL”), an emissive layer, an electron transport layer (“ETL”), and a cathode, and may include additional layers. The emissive layer usually consists of a dopant and, optionally, a host, where the dopant is light emitting. Holes and electrons are injected into the emissive layer either directly to the dopant molecule or indirectly to the host molecule and then to the dopant. The recombination energy generates electroluminescence from the dopant. The energy gap for these materials is determined by ionization potential (“IP”) and electron affinity (“EA”). In the emissive layer, the energy gap of the host (IP_{HO}-EA_{HO}), if present, is always larger than the energy gap of the dopant (IPₑₘₜ-EAₑₘₜ), so if recombination occurs on the host molecules, energy can be transferred to the dopant molecule generating electroluminescence.

There is a continuing need for improved emissive layers in OLED devices.

### SUMMARY

There is provided an organic light emitting diode comprising an anode, a hole transport layer comprising a material having an ionization potential IP_{HTL}, an emissive layer, an electron transport layer, and a cathode, wherein the emissive layer comprises:

(a) a fluorinated iridium complex emitter having an ionization potential IPₑₘₜ;

(b) an electron transport host having an ionization potential IP_{HO}; and

(c) a recombination zone shifting additive having an ionization potential IPₓ;

and wherein:

(IP_{HTL}−IPₑₘₜ)≧−0.1 eV; (i)

IP_{HO}>IP_{HTL}; and (ii)

IPₓ≦IP_{HTL}; (iii)

and where the weight ratio of host to zone shifting additive is at least 4.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1(a) includes a schematic diagram of the energy levels in a prior art device.

FIG. 1(b) includes a schematic diagram of the energy levels in a prior art device.

FIG. 2 includes a schematic diagram of the energy levels in a device with a ternary emissive layer.

FIG. 3 includes a schematic diagram of an OLED device.

Skilled artisans will appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans will appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Emissive Layer, the OLED Device, and finally Examples.

### 1. Definitions and Clarification of Terms

Before addressing details of embodiments described below, some terms are defined or clarified.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport material facilitate negative charge. Although light-emitting materials may also have some charge transport properties, the term “charge transport layer, material, member, or structure” is not intended to include a layer, material, member, or structure whose primary function is light emission.

The term “dopant” is used interchangeably with the term “emitter”, and is intended to mean any material or combination of materials or layers that emit visible light when a voltage is applied thereto.

The term “electron affinity”, EA, of an atom or molecule is intended to mean the energy required to detach an electron from a singly charged negative ion, i.e., the energy change for the process

X⁻→X+e⁻

An equivalent definition is the energy released (EAᵢₙᵢₜᵢₐₗ-EA_{final}) when an electron is attached to a neutral atom or molecule. It should be noted that the sign convention for EA is the opposite of most thermodynamic quantities: a positive electron affinity indicates that energy is released on going from atom to anion.

Electron affinity of a solid film is commonly measured by Inverse Photoemission Spectroscopy (IPES). Electron affinity is also frequently identified in the art as the Lowest Un-occupied Molecular Orbital (LUMO) of the molecule, or as the electron transport level of the molecule.

The term “emissive layer” is intended to mean the layer of a device from which light is generated and emitted.

The prefix “fluoro” and the term “fluorinated” indicate that one or more hydrogen atoms have been replaced with a fluorine atom.

The term “fluorinated iridium complex” is intended to mean a coordination complex of iridium having at least one ligand that is fluorinated.

The term “hexacoordinate” refers to a molecule with six ligands or atomic attachments arranged around a single metal atom in the center. Most hexacoordinate species form an octachedral molecular geometry, with four ligands arranged equatorially, and two axially. The term “ligand” is intended to mean a molecule, ion, or atom that is attached to the coordination sphere of a metallic atom or ion. The suffix “dentate” refers to the number of coordinating sites for a ligand. A monodentate ligand coordinates to a metal at one place; a bidentate ligand coordinates to a metal at two places; a tridentate ligand, at three places, etc.

The term “host” is intended to mean a material in which an emitter material is dispersed. The host is present at a concentration greater than 50% in the emissive layer.

The term “ionization potential”, IP, of an atom or molecule is the energy required to remove one mole of electrons from one mole of isolated gaseous atoms or ions. As used herein, only the first ionization potential will be considered. IP is considered in physical chemistry as a measure of the “reluctance” of an atom or ion to surrender an electron, or the “strength” by which the electron is bonded; the greater the ionization energy, the more difficult it is to remove an electron.

Ionization potential of a solid film is commonly measured by Ultraviolet Photoemission Spectroscopy (UPS). Ionization potential is also frequently identified as the Highest Occupied Molecular Orbital (HOMO) of the molecule, or as the hole transport level of the molecule in the art.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Emissive Layer

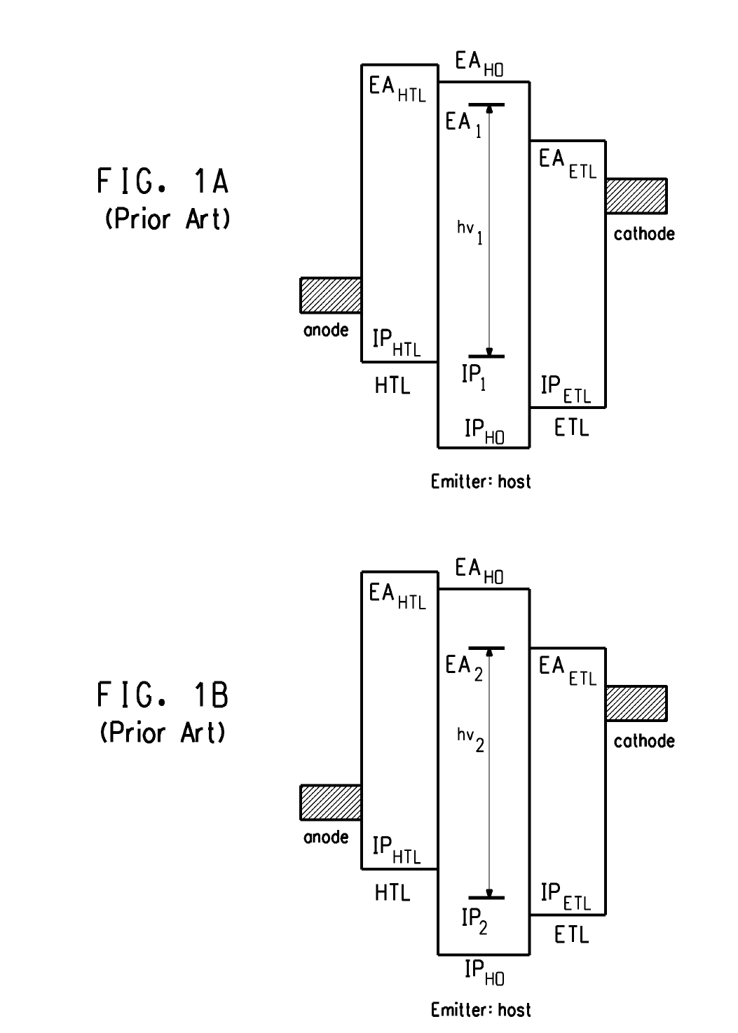

In OLEDs having a dopant-host system, compromise has to be made when designing efficient electroluminescent devices. The electroluminescent color of a device is shown as hν₁ and hν₂ in FIGS. 1(a) and 1(b), respectively. If one wants to make the electroluminescent color constant as required for full color display applications, then the ionization potential and electron affinity of the dopant molecule cannot be independently adjusted to optimize device performance. For example, if one tries to align the ionization potential of the dopant (IP₁ in FIG. 1(a)) to the ionization potential of the hole transport layer (IP_{HTL}), hole injection from HTL to the dopant will be enhanced, but electron injection from the electron transport layer is often compromised. Conversely, if one tries to align the electron affinity of the dopant (EA₂ in FIG. 1(b)) to the electron affinity of the electron transport layer (EA_{ETL}), electron injection from ETL to the dopant will be enhanced, but hole injection from the hole transport layer often suffers.

This same limitation also applies to charge transport and trapping in the emissive layer, which can affect both device efficiency and lifetime. For example, if one wishes to align the ionization potential of the dopant (IP₁ or IP₂) to the ionization potential of the host (IP_{HO}) to minimize hole trapping, the electron affinity of the dopant (EA₁ or EA₂) has to be decreased in order to keep the emitting wavelength constant. This causes more electron trapping. Conversely, if one wishes to align the electron affinity of the dopant (EA₁ or EA₂) to the electron affinity of the host (EA_{HO}), electron trapping will be minimized but hole trapping will be enhanced.

Fluorinated Iridium compounds are known to be good emissive materials in OLEDs, as discussed, for example in Wang et al, Appl. Phys. Lett., 79[4], 449 (2001). They have many advantages over non-fluorinated Ir compounds such as easier sublimation and less self-quenching thus higher luminescence efficiency. However, one problem with fluorinated Iridium compounds is their higher ionization potentials, compared to the non-fluorinated compounds, as shown by Wang et al. This makes it difficult to inject holes into the emissive layer and thus affects device efficiency and lifetime. This situation corresponds to the case shown in FIG. 1(b).

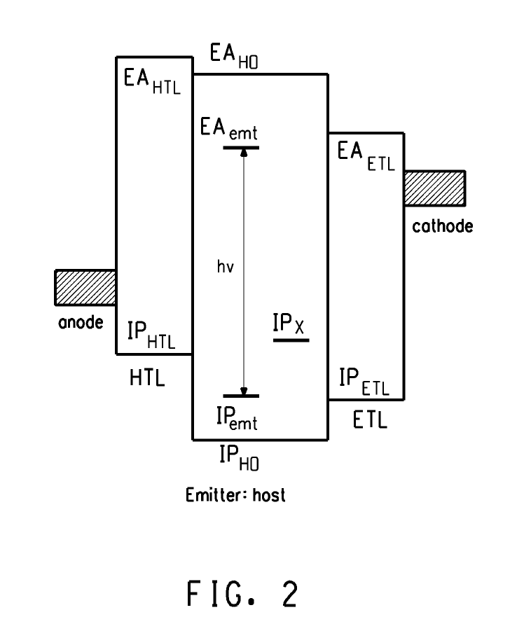

Herein is disclosed a novel device configuration that can compensate for the problem of fluorinated iridium emitter and leads to devices with higher efficiency and longer lifetime. This novel device configuration utilizes an emissive layer that contains: (1) a fluorinated iridium emitter; (2) an electron transport host material; and (3) a recombination zone shifting additive. This additive can enhance hole injection and shift the electron-hole recombination zone slightly into the emissive layer (towards cathode). The concentration of this additive in the emitter layer is below the concentration where it will enhance hole transport through the whole emissive layer and thus reduce device efficiency. The energy levels of this device are shown in FIG. 2.

The emissive layer of the device having the new configuration comprises:

(a) a fluorinated iridium complex emitter;

(b) an electron transport host; and

(c) a recombination zone shifting additive;

where:

(IP_{HTL}−IPₑₘₜ)≧−0.1 eV; (i)

IP_{HO}>IP_{HTL}; and (ii)

IPₓ≦IP_{HTL}; (iii)

and where the weight ratio of host to zone shifting additive is at least 4:1. IPₑₘₜ is the ionization potential of the emitter, IP_{HTL} is the ionization potential of the hole transport layer; IPₓ is the ionization potential of the additive. Positive values have been adopted for all ionization potentials. In some embodiments, there will be more than one hole transport layer in a device. In this case, IP_{HTL} is taken as the ionization potential of the hole transport material in the layer immediately adjacent and closest to the emissive layer.

In some embodiments, the weight ratio of host to zone shifting additive is greater than 4:1. In some embodiments, the ratio is in the range of 5:1 to 20:1; in some embodiments, the ratio is in the range of 9:1 to 15:1.

In some embodiments, the weight ratio of host to emitter is in the range of 5:1 to 20:1; in some embodiments, 8:1 to 13:1.

The term “layer” is used interchangeably with the term “film” and refers to a coating covering a desired area. The term is not limited by size. The area can be as large as an entire device or as small as a specific functional area such as the actual visual display, or as small as a single sub-pixel. The emissive layer can be formed by any conventional deposition technique, including vapor deposition, liquid deposition (continuous and discontinuous techniques), and thermal transfer. With thermal evaporation, there can be a single deposition of a ternary mixture of all three compounds. There can also be a co-deposition of the emitter and a binary mixture of the electron transport host and zone shifting additive. The mixtures can be prepared by thorough mixing of the individual components in power form using commonly available mixing and grinding techniques such as ball milling, Hammer/Cutter milling, and freeze milling. The mixtures can be used in the powder form or they can be pressed into a compact disc with high pressure.

For liquid deposition, the materials are dissolved or dispersed in a liquid medium and applied to form a film. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

(a) Fluorinated iridium complex

The emitter is a coordination complex of Ir(III) having at least one fluorinated ligand. Theft is hexacoordinate and the complex is electrically neutral. In some embodiments, the fluorinated ligand is a multidentate cyclometalating ligand coordinated through at least one carbon and at least one nitrogen. The ligand can be bidentate, forming one ring with the iridium; tridentate, forming two rings with the iridium; or higher.

The iridium complex emitter is present in an amount of about 1-25 weight %, based on the total weight of the emissive layer; in some embodiments, 5-10 weight %.

In some embodiments, the emitter is a complex having the formula Ir(L1)ₐ(L2)_{b} (L3)_{c}; where

L1 is a fluorinated monoanionic bidentate cyclometalating ligand coordinated through carbon and nitrogen;

L2 is a monoanionic bidentate ligand which is not coordinated through a carbon;

L3 is a monodentate ligand;

a is 1-3;

b and c are independently 0-2;

and a, b, and c are selected such that the iridium is hexacoordinate and the complex is electrically neutral.

Some examples of formulae include, but are not limited to, Ir(L1)₃; Ir(L1)₂(L2); and Ir(L1)₂(L3)(L3′), where L3 is anionic and L3′ is nonionic.

Examples of L1 ligands include, but are not limited to fluorinated derivatives of phenylpyridines, phenylquinolines, phenylpyrimidines, phenylpyrazoles, thienylpyridines, thienylquinolines, and thienylpyrimidines. As used herein, the term “quinolines” includes “isoquinolines” unless otherwise specified. The fluorinated derivatives can have one or more fluorine substituents. In some embodiments, there are 1-3 fluorine substituents on the non-nitrogen ring of the ligand.

Monoanionic bidentate ligands, L2, are well known in the art of metal coordination chemistry. In general these ligands have N, O, P, or S as coordinating atoms and form 5- or 6-membered rings when coordinated to the iridium. Suitable coordinating groups include amino, imino, amido, alkoxide, carboxylate, phosphino, thiolate, and the like. Examples of suitable parent compounds for these ligands include β-dicarbonyls (β-enolate ligands), and their N and S analogs; amino carboxylic acids (aminocarboxylate ligands); pyridine carboxylic acids (iminocarboxylate ligands); salicylic acid derivatives (salicylate ligands); hydroxyquinolines (hydroxyquinolinate ligands) and their S analogs; and phosphinoalkanols (phosphinoalkoxide ligands).

Monodentate ligand L3 can be anionic or nonionic. Anionic ligands include, but are not limited to, H⁻ (“hydride”) and ligands having C, O or S as coordinating atoms. Coordinating groups include, but are not limited to alkoxide, carboxylate, thiocarboxylate, dithiocarboxylate, sulfonate, thiolate, carbamate, dithiocarbamate, thiocarbazone anions, sulfonamide anions, and the like. In some cases, ligands listed above as L2, such as β-enolates and phosphinoakoxides, can act as monodentate ligands. The monodentate ligand can also be a coordinating anion such as halide, cyanide, isocyanide, nitrate, sulfate, hexahaloantimonate, and the like. These ligands are generally available commercially.

The monodentate L3 ligand can also be a non-ionic ligand, such as CO or a monodentate phosphine ligand.

The fluorinated iridium emitters can be made using standard synthetic techniques as described in, for example, Grushin et al., U.S. Pat. No. 6,670,645.

Some non-limiting examples of specific fluorinated iridium emitters include:

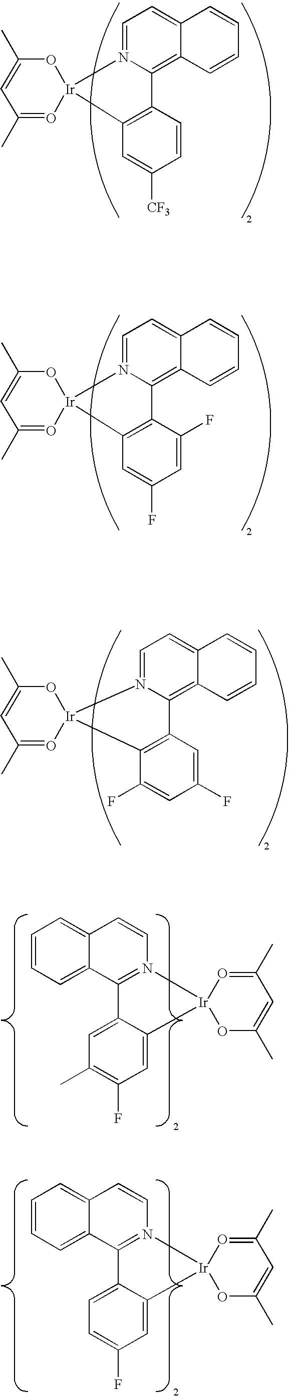

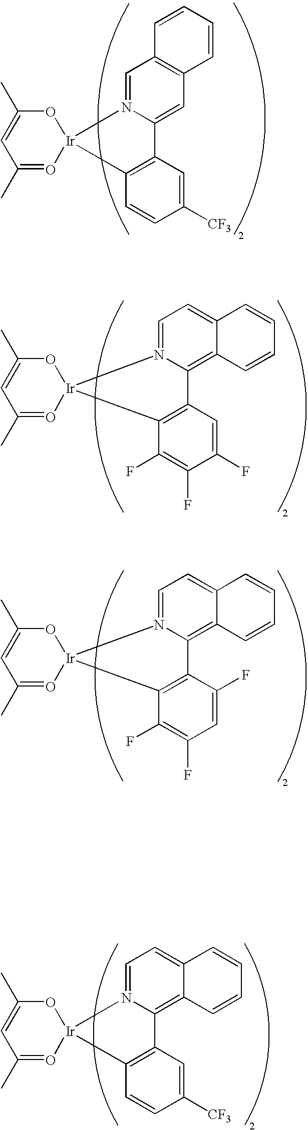

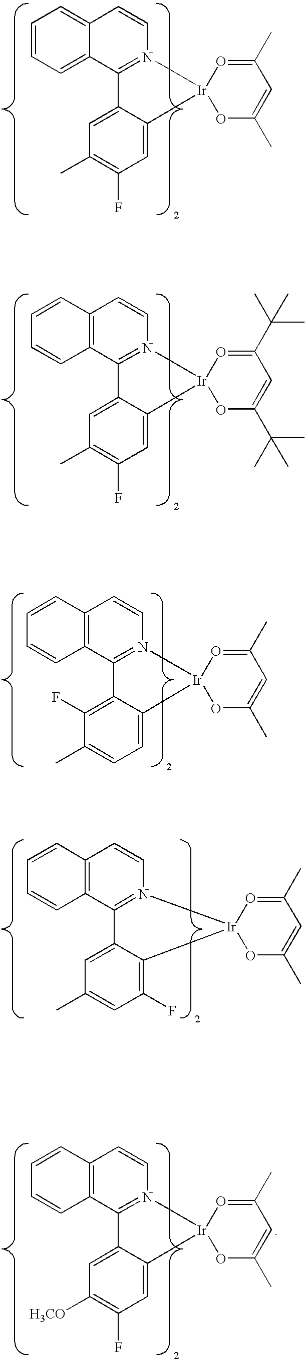

### (b) Electron Transport Host

The host is an electron transport material. The host is generally present in an amount of about 60-98 weight %, based on the total weight of the emissive layer; in some embodiments, 70-85 weight %.

Electron transport materials are known, and include, but are not limited to, metal chelated oxinoid compounds, azole compounds, quinoxalinederivatives, and phenanthrolines.

Metal chelated oxinoid compounds include, but are not limited to, tris(8-hydroxyquinolato)aluminum (AlQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ).

Azole compounds include, but are not limited to, 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI).

Quinoxaline derivatives include, but are not limited to, 2,3-bis(4-fluorophenyl)quinoxaline.

Phenanthrolines include, but are not limited to, 4,7-diphenyl-1,10-phenanthroline (DPA) and 2,9-dimethyl-4,7-diphenyl-1,10-phenanthroline (DDPA).

In some embodiments, a combination of two or more host materials can be used. In this case, the ionization potential of each host will be greater than the ionization potential of the hole transport layer. The total amount of host material will be 60-98 weight %, based on the total weight of the emissive layer, and the weight ratio of the total of all host material to zone shifting additive will be at least 4.

Some non-limiting examples of specific host materials include:

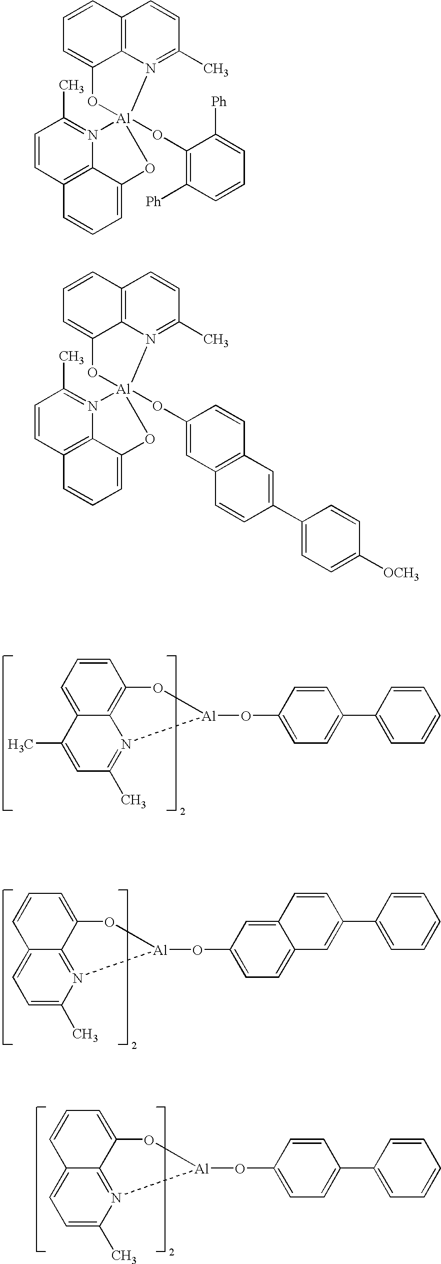

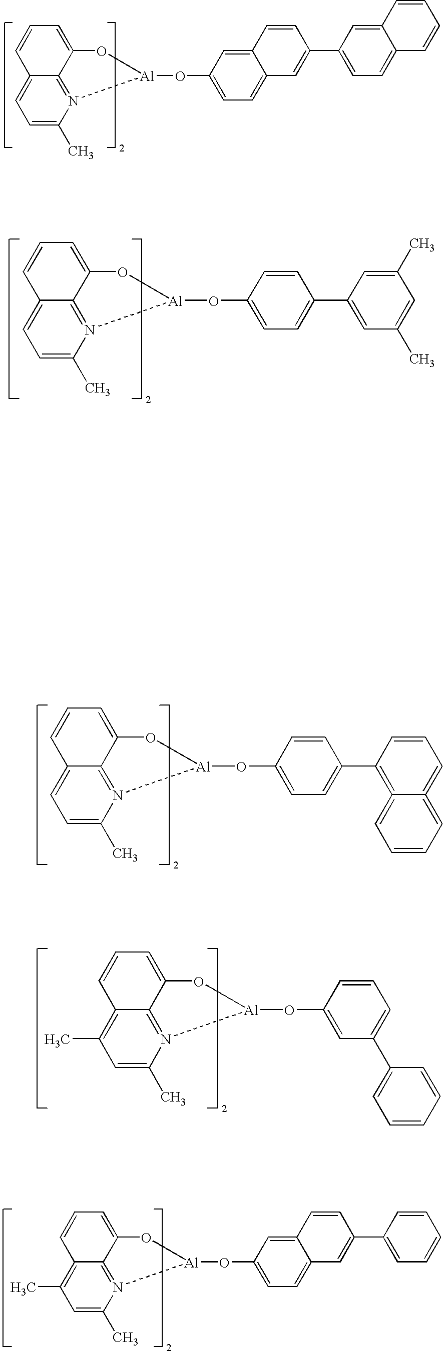

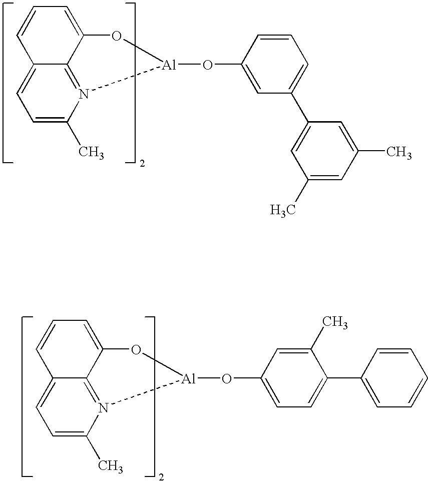

### (c) Recombination Zone Shifting Additive

The recombination additive is a material having an ionization potential that is the same as or less than the ionization potential of the hole transport material in the hole transport layer. In some embodiments, the additive is a compound having triarylamine groups; in some embodiments, the aryl groups are phenyl or naphthyl. In some embodiments, the additive is a derivative of triphenylmethane. In some embodiments, the additive is a carbazole derivative. In some embodiments, the additive is a porphyrinic compound.

In some embodiments, the additive is selected from the group consisting of N,N′-bis(naphthalen-1-yl)-N,N′-bis-(phenyl)benzidine (α-NPB); 4,4′,4″-tris(N,N-diphenyl-amino)-triphenylamine (TDATA); N,N′-diphenyl-N,N′-bis(3-methylphenyl)-[1,1′-biphenyl]-4,4′-diamine (TPD); derivatives thereof; and oligomers thereof. In some embodiments, the derivatives include compounds substituted with 1-5 alkyl groups, phenyl groups, naphthyl groups, diphenylamino groups, and combinations thereof. In some embodiments, the oligomers include two or more of the same type of the compound joined together. In some embodiments, the oligomers include two or more of different types of compounds joined together. In some embodiments, the compound are joined via single bonds or arylene groups.

In some embodiments, the additive is selected from the group consisting of 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′, N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); and N,N,N′,N-tetrakis(4-methylphenyl)-(1,1′-biphenyl)-4,4′-diamine (TTB).

Some additional non-limiting examples of the additive include:

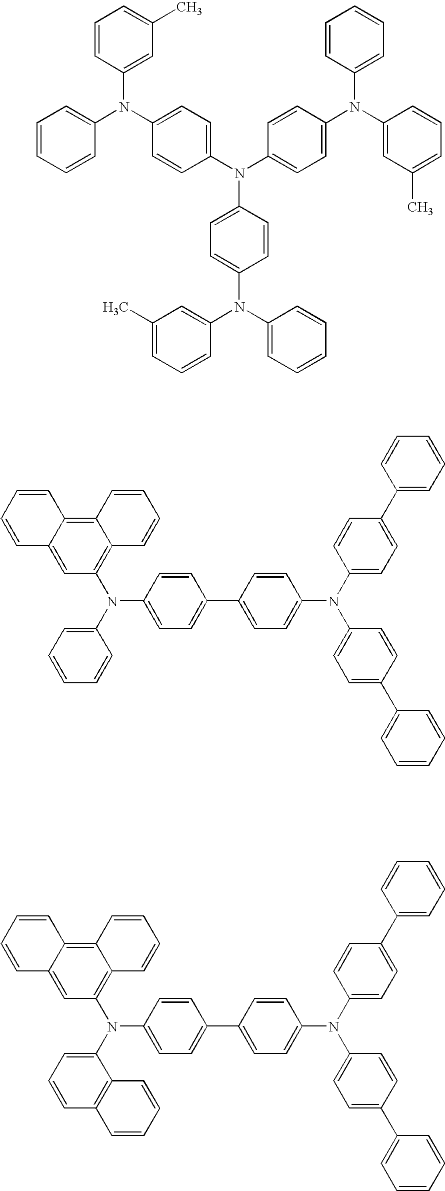

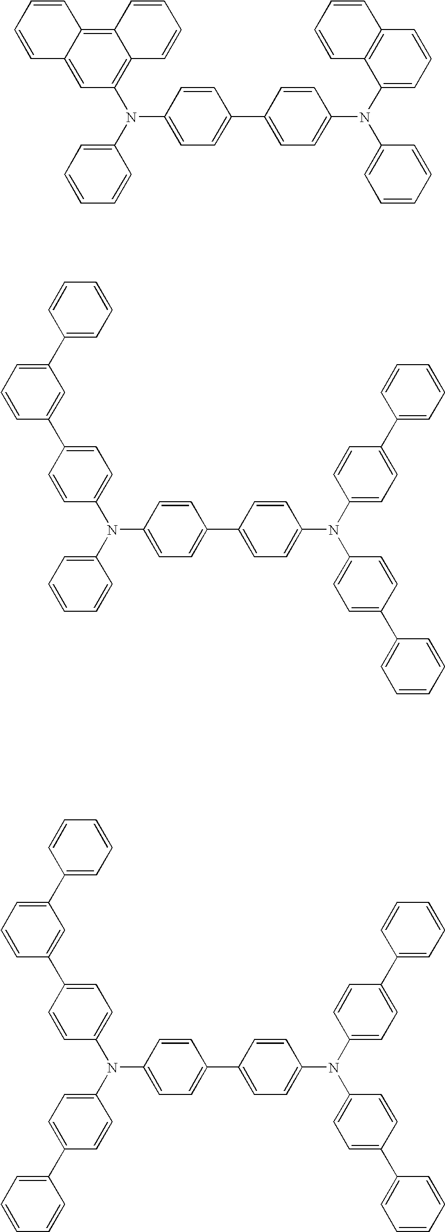

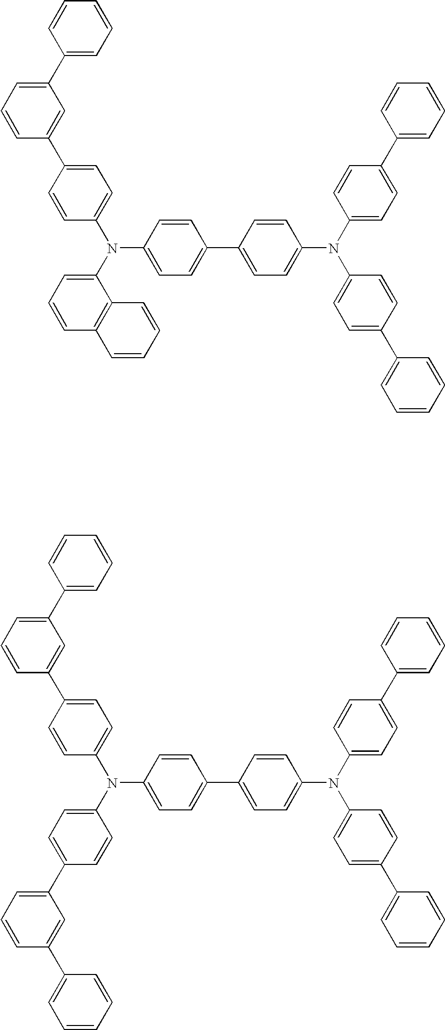

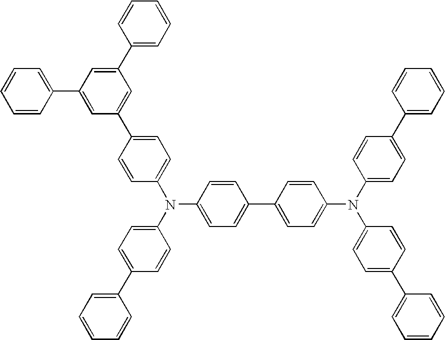

In some embodiments, a combination of two or more additives can be used. In this case, the ionization potential of each additive will be the same as or less than the ionization potential of the hole transport material in the hole transport layer. The weight ratio of host material to the total of all zone shifting additives will be at least 4.

### 3. The OLED Device

Organic electronic devices that may benefit from having one or more emissive layers as described herein include, but are not limited to, (1) devices that convert electrical energy into radiation (e.g., a light-emitting diode, light emitting diode display, or diode laser), (2) devices that detect signals through electronics processes (e.g., photodetectors, photoconductive cells, photoresistors, photoswitches, phototransistors, phototubes, IR detectors), (3) devices that convert radiation into electrical energy, (e.g., a photovoltaic device or solar cell), and (4) devices that include one or more electronic components that include one or more organic semi-conductor layers (e.g., a transistor or diode).

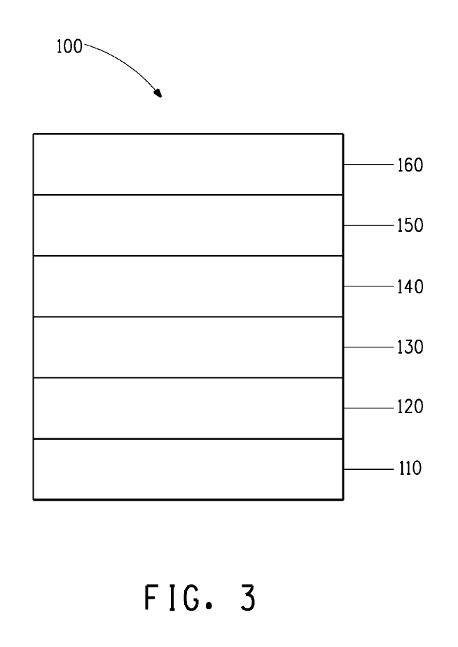

One illustration of an OLED device structure is shown in FIG. 3. The device 100 has an anode layer 110, a hole transport layer 130, an emissive layer 140, and a cathode layer 160. Adjacent to the anode there may be an optional buffer layer 120. Adjacent to the cathode there may be an optional electron transport layer 150. As an option, devices may use one or more additional hole injection or hole transport layers (not shown) next to the anode 110 and/or one or more additional electron injection or electron transport layers (not shown) next to the cathode 160.

In one embodiment, the different layers have the following range of thicknesses: anode 110, 500-5000 Å, in one embodiment 1000-2000 Å; buffer layer 120, 50-2000 Å, in one embodiment 200-1000 Å; hole transport layer 120, 50-2000 Å, in one embodiment 200-1000 Å; photoactive layer 130, 10-2000 Å, in one embodiment 100-1000 Å; layer 140, 50-2000 Å, in one embodiment 100-1000 Å; cathode 150, 200-10000 Å, in one embodiment 300-5000 Å. The desired ratio of layer thicknesses will depend on the exact nature of the materials used.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also comprise an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

Optional buffer layer 120 comprises buffer materials. The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Buffer materials may be polymers, oligomers, or small molecules, and may be in the form of solutions, dispersions, suspensions, emulsions, colloidal mixtures, or other compositions.

The buffer layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The buffer layer 120 can comprise charge transfer compounds, and the like, such as copper phthalocyanine and the tetrathiafulvalene-tetracyanoquinodimethane system (TTF-TCNQ). In one embodiment, the buffer layer 120 is made from a dispersion of a conducting polymer and a colloid-forming polymeric acid. Such materials have been described in, for example, published U.S. patent applications 2004-0102577, 2004-0127637, and 2005/205860.

Layer 130 comprises hole transport material. Examples of hole transport materials for the hole transport layer have been summarized for example, in Kirk-Othmer Encyclopedia of Chemical Technology, Fourth Edition, Vol. 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 4,4′-bis(carbazol-9-yl)biphenyl (CBP); 1,3-bis(carbazol-9-yl)benzene (mCP); 1,1-bis[(di-4-tolylamino)phenyl]cyclohexane (TAPC); N,N-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In some embodiments, the hole transport layer comprises a hole transport polymer. In some embodiments, the hole transport polymer is a distyrylaryl compound. In some embodiments, the aryl group is has two or more fused aromatic rings. In some embodiments, the aryl group is an acene. The term “acene” as used herein refers to a hydrocarbon parent component that contains two or more ortho-fused benzene rings in a straight linear arrangement.

In some embodiments, the hole transport polymer is an arylamine polymer. In some embodiments, it is a copolymer of fluorene and arylamine monomers.

In some embodiments, the polymer has crosslinkable groups. In some embodiments, crosslinking can be accomplished by a heat treatment and/or exposure to UV or visible radiation. Examples of crosslinkable groups include, but are not limited to vinyl, acrylate, perfluorovinylether, 1-benzo-3,4-cyclobutane, siloxane, and methyl esters. Crosslinkable polymers can have advantages in the fabrication of solution-process OLEDs. The application of a soluble polymeric material to form a layer which can be converted into an insoluble film subsequent to deposition, can allow for the fabrication of multilayer solution-processed OLED devices free of layer dissolution problems.

Examples of crosslinkable polymers can be found in, for example, published US patent application 2005-0184287 and published PCT application WO 2005/052027.

In some embodiments, the hole transport layer comprises a polymer which is a copolymer of 9,9-dialkylfluorene and triphenylamine. In some embodiments, the polymer is a copolymer of 9,9-dialkylfluorene and 4,4′-bis(diphenylamino)biphenyl. In some embodiments, the polymer is a copolymer of 9,9-dialkylfluorene and TPB. In some embodiments, the polymer is a copolymer of 9,9-dialkylfluorene and NPB. In some embodiments, the copolymer is made from a third comonomer selected from (vinylphenyl)diphenylamine and 9,9-distyrylfluorene or 9,9-di(vinylbenzyl)fluorene.

Layer 140 is the new emissive layer described herein.

Optional layer 150 is an electron transport material. Examples of electron transport materials which can be used in the optional electron transport layer 150, include metal chelated oxinoid compounds, such as tris(8-hydroxyquinolato)aluminum (AlQ), bis(2-methyl-8-quinolinolato)(p-phenylphenolato) aluminum (BAlq), and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof.

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, and Li₂O can also be deposited between the organic layer and the cathode layer to lower the operating voltage. This layer may be referred to as an electron injection layer.

The device can be fabricated using the same or different standard techniques for each layer. These techniques include vapor deposition, liquid deposition, and thermal transfer. In some embodiments, the anode and cathode are formed using vapor deposition techniques. In some embodiments, all the layers are formed using vapor deposition techniques. In some embodiments, the device is fabricated by liquid deposition of the buffer layer, the hole transport layer, and the emissive layer, and by vapor deposition of the anode, the electron transport layer, an electron injection layer and the cathode.

### EXAMPLES

The concepts described herein will be further described in the following examples, which do not limit the scope of the invention described in the claims.

### Materials:

Buffer 1 is made from a dispersion of a polythiophene and a colloid-forming fluorinated polymeric acid, as described in published U.S. patent application 2004-0102577.
HT-1 is a crosslinkable hole transport polymer having triphenylamine and fluorene units.
NPB is N,N′-Bis(naphthalen-1-yl)-N,N′-bis-(phenyl)benzidine mTDATA is 4,4′,4″-Tris-(N-3-methylphenyl-N-phenyl-amino)-triphenylamine.

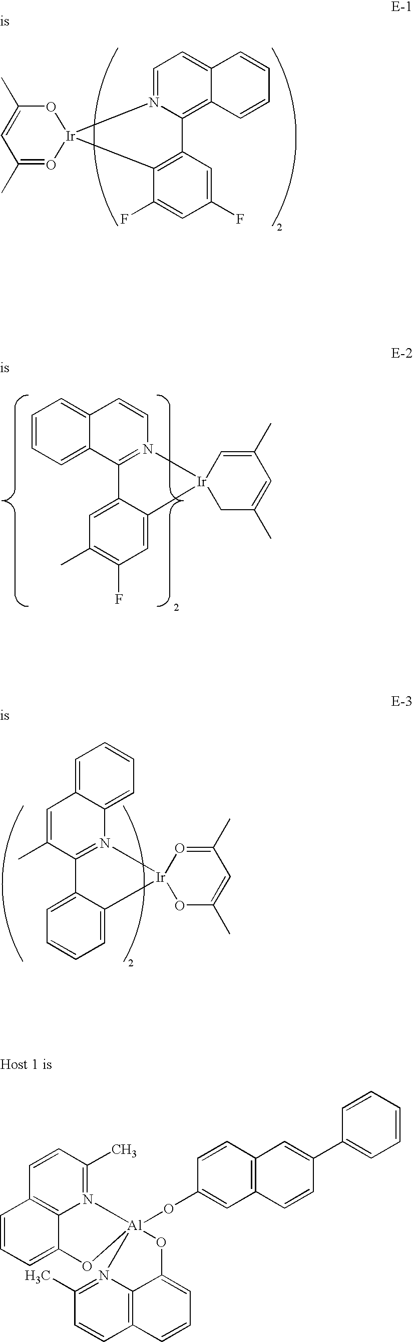

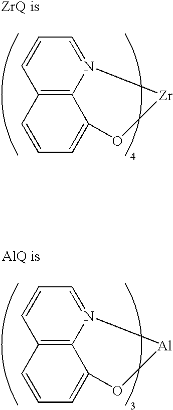

The ionization potentials of materials used are listed in Table I. The device characterization data is summarized in Table II.

### Comparative Example A

This comparative example illustrates a device having no recombination zone shifting additive in the emissive layer.

A device was made with the standard thermal vapor deposition technique. A substrate with 140 nm indium tin oxide was used as the anode. A 80 nm thick mTDATA layer was used as the hole transport layer. The emissive layer consisted of emitter E-1 doped in Host 1. The host:dopant weight ratio was 12.5:1 and the layer thickness was 43 nm. AlQ of 30 nm thick was used as the electron transport layer. LiF (1 nm)/Al (100 nm) was the cathode.

### Example 1

This example illustrates a device using mTDATA as a recombination zone shifting additive.

A device was made with the standard thermal vapor deposition technique. A substrate with 140 nm indium tin oxide was used as the anode. A 80 nm thick mTDATA layer was used as the hole transport layer. The emissive layer was 43 nm thick and consisted of emitter E-1 doped in a mixture of Host 1 with mTDATA as the additive. The weight ratio of (host+additive):emitter was 12.5:1; the weight ratio of host:additive was 4:1. An AlQ layer 30 nm thick was used as the electron transport layer. LiF (1 nm)/Al (100 nm) was the cathode.

The ionization potentials of materials used are listed in Table I. The device characterization data is summarized in Table II.

### Examples 2-4 and Comparative Examples B-F

In these examples, devices were made by a combination of solution processing and vapor deposition techniques. A substrate with 140 nm indium tin oxide was used as the anode. Buffer 1 was applied by spin coating from an aqueous dispersion. HT-1 was applied by spin coating from a toluene solution. The other materials were applied by evaporative deposition.

### Comparative Example B

This comparative example illustrates a device in which the emissive layer does not include a recombination zone shifting additive.

Buffer 1 was 50 nm thick.

A first hole transport layer of HT-1 was 18 nm thick

A second hole transport layer of NPB was 10 nm thick

An emissive layer was 43 nm thick and consisted of emitter E-2 doped in Host 1, with a host:dopant weight ratio of 12.5:1.

An electron transport layer of ZrQ was 30 nm thick.

The cathode was LiF (1 nm)/Al(100 nm).

### Example 2

This example illustrates a device using NPB as a recombination zone additive.

Buffer 1 was 50 nm thick.

A first hole transport layer of HT-1 was 18 nm thick

A second hole transport layer of NPB was 10 nm thick

An emissive layer was 43 nm thick and consisted of emitter E-2 doped in a mixture of Host 1 and NPB as the additive. The weight ratio of (host+additive):emitter was 12.5:1; the weight ratio of host:additive was 4:1.

An electron transport layer of ZrQ was 30 nm thick.

The cathode was LiF (1 nm)/Al(100 nm).

### Example 3

This example illustrates a device using NPB as a recombination zone additive. The level of NPB is lower than in Example 2.

Buffer 1 was 50 nm thick.

A first hole transport layer of HT-1 was 18 nm thick

A second hole transport layer of NPB was 10 nm thick

An emissive layer was 43 nm thick and consisted of emitter E-2 doped in a mixture of Host 1 and NPB as the additive. The weight ratio of (host+additive):emitter was 12.5:1; the weight ratio of host:additive was 9:1.

An electron transport layer of ZrQ was 30 nm thick.

The cathode was LiF (1 nm)/Al (100 nm).

### Example 4

This example illustrates a device using NPB as a recombination zone additive. The level of NPB is lower than in Example 3.

Buffer 1 was 50 nm thick.

A first hole transport layer of HT-1 was 18 nm thick

A second hole transport layer of NPB was 10 nm thick

An emissive layer was 43 nm thick and consisted of emitter E-2 doped in a mixture of Host 1 and NPB as the additive. The weight ratio of (host+additive):emitter was 12.5:1; the weight ratio of host:additive was 19:1.

An electron transport layer of ZrQ was 30 nm thick.

The cathode was LiF (1 nm)/Al(100 nm).

### Comparative Example C

This comparative example illustrates a device using NPB as a recombination zone additive, where the host:additive ratio is less than 4:1. The level of NPB is much higher than in Examples 2, 3 and 4.

Buffer 1 was 50 nm thick.

A first hole transport layer of HT-1 was 18 nm thick

A second hole transport layer of NPB was 10 nm thick

An emissive layer was 43 nm thick and consisted of emitter E-2 doped in a mixture of Host 1 and NPB as the additive. The weight ratio of (host+additive):emitter was 12.5:1; the weight ratio of host:additive was 2:1.

An electron transport layer of ZrQ was 30 nm thick.

The cathode was LiF (1 nm)/Al (100 nm).

### Comparative Example D

This comparative example illustrates a device using a non-fluorinated emitter.

Buffer 1 was 65 nm thick.

A hole transport layer of NPB was 30 nm thick

An emissive layer was 43 nm thick and consisted of emitter E-3 doped in Host 1. The weight ratio of host:emitter was 12.5:1.

An electron transport layer of ZrQ was 30 nm thick.

The cathode was LiF (1 nm)/Al (100 nm).

### Comparative Example E

This comparative example illustrates a device using a non-fluorinated emitter and using NPB.

Buffer 1 was 65 nm thick.

A hole transport layer of NPB was 30 nm thick

An emissive layer was 43 nm thick and consisted of emitter E-3 doped in a mixture of Host 1 and NPB as the additive. The weight ratio of (host+additive):emitter was 12.5:1; the weight ratio of host:additive was 9:1.

An electron transport layer of ZrQ was 30 nm thick.

The cathode was LiF (1 nm)/Al (100 nm).

TABLE I
Ionization potentials of materials measured by UPS>

| | Ionization |
|---|---|
| Material | potential, eV |
| NPB | 5.4 |
| mTDATA | 5.0 |
| Host 1 | 6.1 |
| ZrQ | 5.7 |
| AlQ | 5.8 |
| E-1 | 5.6 |
| E-2 | 5.4 |
| E-3 | 5.1 |

TABLE II
Device data for examples 1-9.

| | | | Color |
|---|---|---|---|
| | Efficiency at | Efficiency at | coordinates, |
| Example | 500 nits, cd/A | 1000 nits, cd/A | (x, y) |
| Comparative A | 7.7 | 7.4 | (0.65, 0.35) |
| Example 1 | 10.2 | 9.4 | (0.65, 0.35) |
| Comparative B | 17.8 | 16.4 | (0.65, 0.35) |
| Example 2 | 20.5 | 20.8 | (0.65, 0.35) |
| Example 3 | 24.2 | 23.6 | (0.65, 0.35) |
| Example 4 | 23.3 | 21.8 | (0.65, 0.35) |
| Comparative C | 10 | 11 | (0.65, 0.35) |
| Comparative D | 15.5 | 14.2 | (0.65, 0.35) |
| Comparative E | 13.5 | 13.6 | (0.65, 0.35) |

Comparative Example A has only Host 1 and emitter E-1 in the emissive layer. Example 1 has Host 1, red1, and mTDATA as a recombination zone shifting additive in the emissive layer, with a host:additive weight ratio of 4:1. Comparison of Comparative Example A and Example 1 shows the addition of mTDATA in the specified amount to the emissive layer enhances the electroluminescent efficiency of emitter E-1 devices.

Comparative Example B has only Host 1 and emitter E-2 in the emissive layer. Examples 2, 3, and 4 have Host 1, emitter E-2, and NPB as a recombination zone shifting additive in the emissive layer. Comparison of Example 3 and Examples 4 to 6 shows the addition of NPB to the emissive layer with host:additive weight ratios of 4:1, 9:1, and 19:1 all improve the electroluminescent efficiency of emitter E-2 devices.

Comparative Example B has only Host 1 and emitter E-2 in the emissive layer. Comparative Example C has Host 1, emitter E-2, and NPB as an additive in the emissive layer. However, the host:additive weight ratio is 2:1, which is less than the 4:1 ratio described hereinabove. Comparison of Comparative Examples B and C shows that the addition of NPB to the emissive layer in this high amount results in a reduction of the electroluminescent efficiency for emitter E-2 devices.

Comparative Example D has only Host 1 and emitter E-3 in the emissive layer. Example 9 has Host 1, emitter E-3, and NPB as an additive in the emissive layer, with a host:additive ratio of 4:1. However, emitter E-3 is not fluorinated. Comparison of Comparative Examples D and E shows that the addition of NPB to the emissive layer results in a reduction of the electroluminescent efficiency for emitter E-3 (non-fluorinated) devices.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination.

What is claimed is:

1. An organic light emitting diode comprising an anode, a hole transport layer comprising a material having an ionization potential IP_{HTL}, an emissive layer, an electron transport layer, and a cathode, wherein the emissive layer comprises:
(a) a fluorinated iridium complex emitter having an ionization potential IPₑₘₜ;
(b) an electron transport host having an ionization potential IP_{HO}; and
(c) a recombination zone shifting additive having an ionization potential IPₓ;
and wherein:
(IP_{HTL}−IPₑₘₜ)≧−0.1 eV; (i)
IP_{HO}>IP_{HTL}; and (ii)
IPₓ≦IP_{HTL}; (iii)
and where the weight ratio of host to zone shifting additive is at least 4.

2. The diode of claim 1, wherein the emitter has at least one fluorinated multidentate cyclometalating ligand coordinated through at least one carbon and at least one nitrogen.

3. The diode of claim 1, wherein the emitter is a complex having the formula Ir(L1)ₐ(L2)_{b}(L3)_{c}; where
L1 is a fluorinated monoanionic bidentate cyclometalating ligand coordinated through carbon and nitrogen;
L2 is a monoanionic bidentate ligand which is not coordinated through a carbon;
L3 is a monodentate ligand;
a is 1-3;
b and c are independently 0-2;
and a, b, and c are selected such that the iridium is hexacoordinate and the complex is electrically neutral.

4. The diode of claim 3, wherein L1 is selected from the group consisting of fluorinated derivatives of phenylpyridines, phenylquinolines, phenylpyrimidines, phenylpyrazoles, thienylpyridines, thienylquinolines, and thienylpyrimidines.

5. The diode of claim 4, wherein a=2, b=1, c=0, and L2 is selected from the group consisting of β-enolate ligands, N analogs of β-enolate ligands, S analogs of β-enolate ligands, aminocarboxylate ligands, iminocarboxylate ligands, salicylate ligands, hydroxyquinolinate ligands, S analogs of hydroxyquinolinate ligands, and phosphinoalkoxide ligands.

6. The diode of claim 1, wherein the iridium emitter complex is selected from the group consisting of:

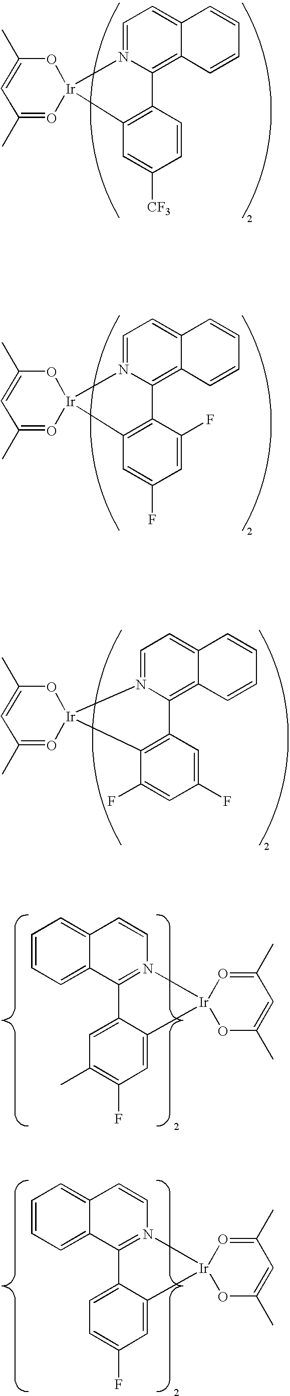

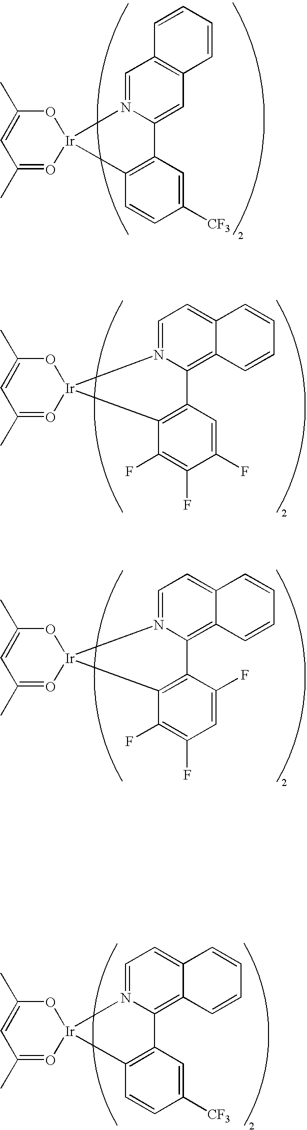

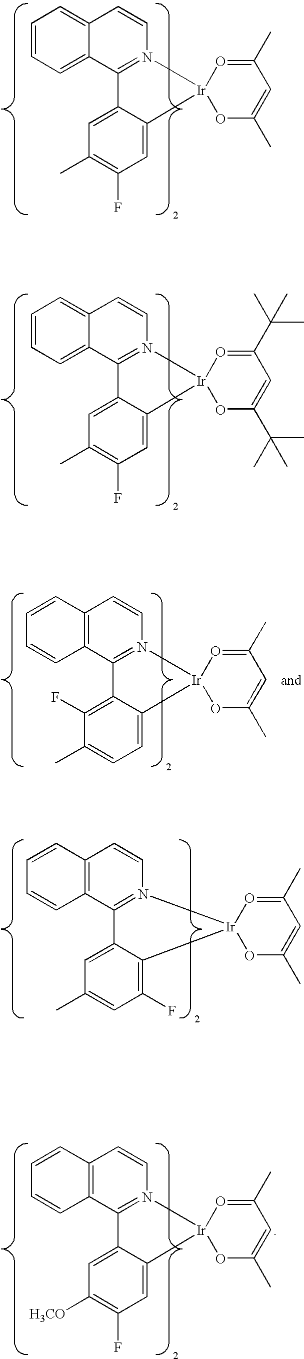

7. The diode of claim 1, wherein the host is selected from the group consisting of metal chelated oxinoid compounds, azole compounds, quinoxalinederivatives, phenanthrolines, and combinations thereof.

8. The diode of claim 7, wherein the host is selected from the group consisting of:

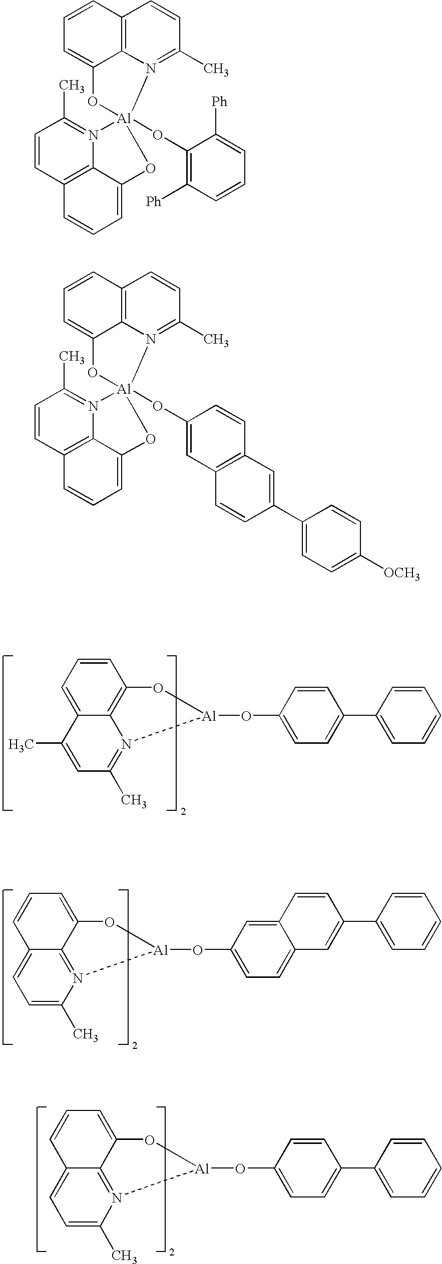

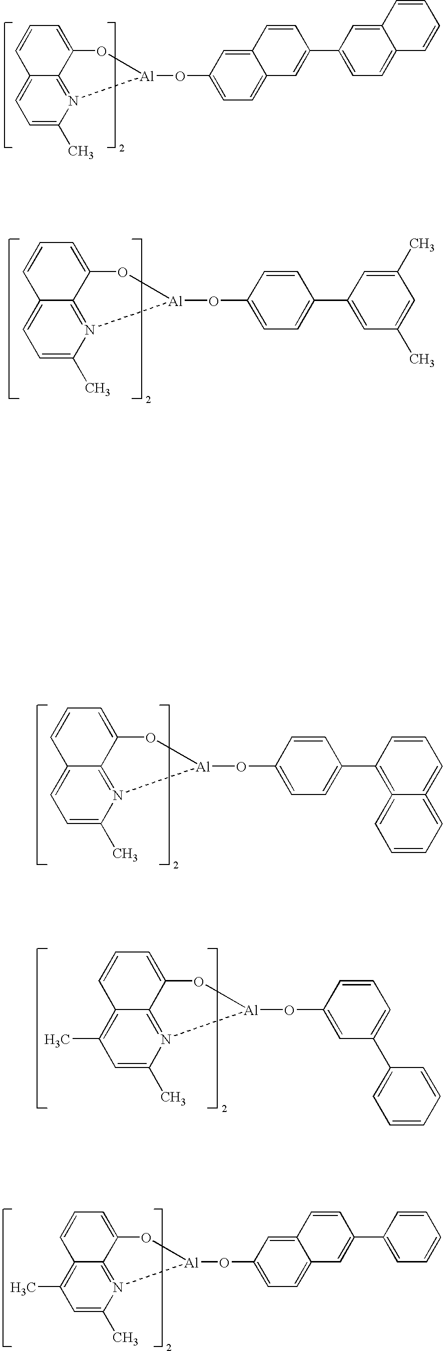

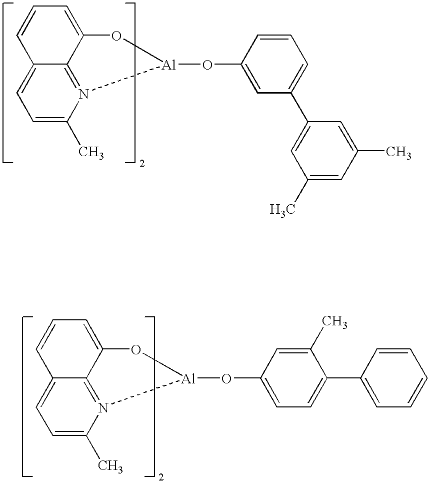

9. The diode of claim 1, wherein the additive is selected from the group consisting of N,N′-bis(naphthalen-1-yl)-N,N′-bis-(phenyl)benzidine (α-NPB); 4,4′,4″-tris(N,N-diphenyl-amino)-triphenylamine (TDATA); 4,4′,4″-tris(N-3-methylphenyl-N-phenylamino)-triphenylamine (mTDATA); N,N′-diphenyl-N,N′-bis(3-methylphenyl)-[1,1′-biphenyl]-4,4′-diamine (TPD); derivatives thereof; oligomers thereof, and mixtures thereof.

10. The diode of claim 1, wherein the additive is selected from the group consisting of 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′, N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); and N,N,N′,N′-tetrakis(4-methylphenyl)-(1,1′-biphenyl)-4,4′-diamine (TTB).

11. The diode of claim 1, wherein the additive is selected from the group consisting of:

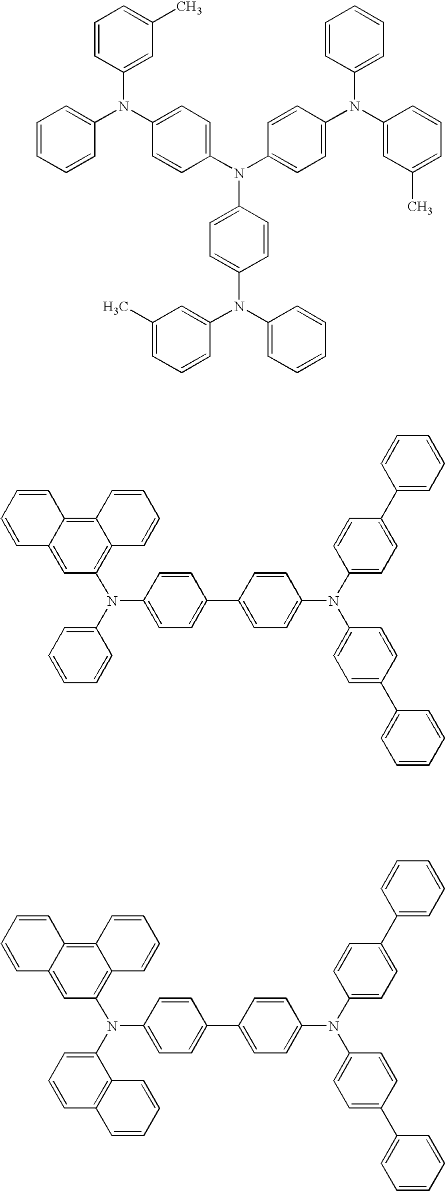

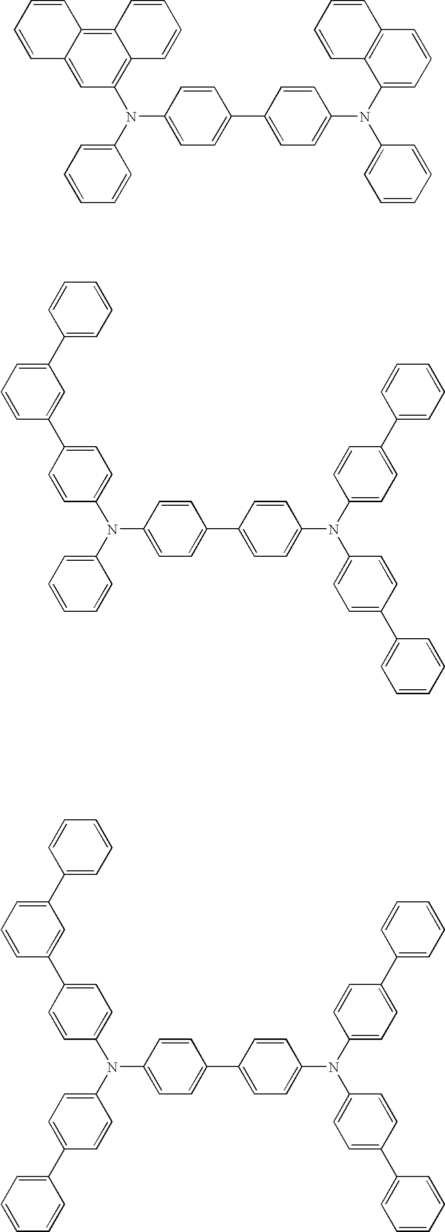

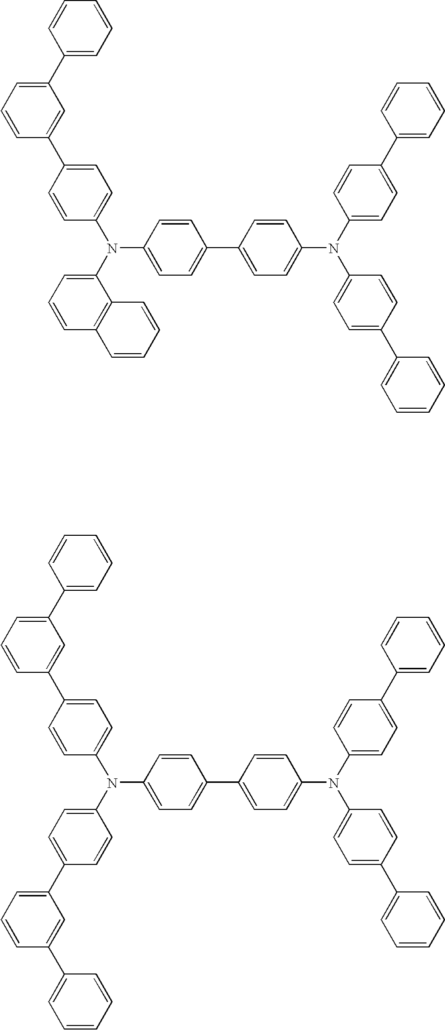

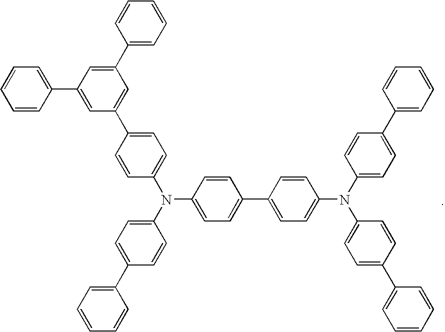

12. The diode of claim 1, wherein the weight ratio of host to zone shifting additive is in the range of 5:1 to 20:1.

13. The diode of claim 1, wherein the weight ratio of host to emitter is in the range of 5:1 to 20:1.

14. The diode of claim 13, wherein the weight ratio of host to emitter is in the range of 8:1 to 13:1.

15. The diode of claim 3, wherein the emitter complex has a formula selected from:
Ir(L1)₂(L2) and Ir(L1)₂(L3)(L3′)
Where L3 is anionic and L3′ is nonionic.
